(19) United States
(12) Patent Application Publication
(10) Pub. No.: US 2005/0034045 A1
(43) Pub. Date: Feb. 10, 2005

(54) System for optimizing PCI-Express communications

(76) Inventors: Andrew W. Lueck, Plano, TX (US); Kevin Keith Main, Plano, TX (US)

Correspondence Address: TEXAS INSTRUMENTS INCORPORATED, P O BOX 655474, M/S 3999, DALLAS, TX, 75265, US

(21) Appl. No.: 10/637,291

(22) Filed: Aug. 8, 2003

(51) Int. Cl. H04L 1/00; G06F 11/00; H03M 13/00; G08C 25/00; G06F 11/30

(52) U.S. Cl. 714/746

(57) ABSTRACT

The present invention provides a system for conducting communications in a PCI-Express system (300). The PCI-Express system is interfaced with a system utilizing another protocol—particularly PCI. The present invention provides a segregation structure (302) within the PCI-Express system. A data transaction, from the PCI system to the PCI-Express system, is initiated. Data transmission is routed through the segregation structure, which operates such that corrupted data within the data transmission is identified and separated from uncorrupted data within the data transmission. The present invention transmits the corrupted data separately from the uncorrupted data.

### TECHNICAL FIELD OF THE INVENTION

The present invention relates generally to the field of computer systems architecture and, more particularly, to a system for optimizing read/write performance in a PCI-Express system that is interfaced with a PCI system.

### BACKGROUND OF THE INVENTION

The speed and performance of modem computer systems continue to advance at an astounding rate. New and improved hardware and software technologies are continually being developed to improve the processing capacities of computers. Usually, such technological advances represent some improvement over previous technologies. Often, however, the new technologies are intended to completely replace the older-rendering them obsolete.

This rapid technological advance creates a number of challenges and problems for computer system designers. Interoperability of systems produced by a wide variety of manufacturers is essential to commercial success. Certain standards for device interfaces and operational protocols must be established and utilized for new technologies. Furthermore, a broad base of existing (or “legacy”) computer systems—utilizing the older, disparate technologies—must be supported to allow end users to migrate to the new technologies without completing replacing their systems every few months. Computer system architects are thus constantly challenged with striking a balance between: extracting optimal performance from new technologies, addressing interoperability requirements, and meeting the needs of legacy system support.

Frequently, such concerns and considerations are addressed through the establishment and observance of industry-wide standards. Various manufacturers and other interested parties collectively determine, for a given technology or technological function, certain required physical and performance parameters. Interoperability and legacy support issues are commonly addressed, as are minimum and maximum performance expectations. Having a standard from which to work, computer system architects may then begin the process of optimizing a particular hardware or software function's design and operation.

Industry standards have been widely relied upon in the design and manufacture a number of computer system components and functions. One particular example is computer bus architectures. Generally speaking, computer bus architectures are concerned with the interface and communication between processing, memory, and input/output system components. One commonly used bus interface is PCI. At the time it was developed, PCI was a very advanced, high-performance parallel bus standard. More recently, a newer bus standard has been developed to more fully utilize new communications technologies (e.g., packet-based, point-to-point). This standard has been called PCI-Express.

Although PCI-Express is intended to eventually replace PCI, it must offer legacy support for existing PCI systems and components. Certain PCI protocol communications and operations must be translated into the proper PCI-Express communication or operation, and vice-versa. With a large number of both PCI and PCI-Express system operations communications, the process of translating between the two gives rise to a number of concerns and considerations.

One such consideration is the process of error detection and handling, and its effects on the efficiency of PCI-Express communications. Under current PCI-Express standards, PCI parity bit errors that occur during read or write transactions are passed to PCI-Express using the EP bit in the PCI-Express packet header. This EP bit indicates that data in the packet is invalid, but does not distinguish the specific location of the error within the data payload. Thus, setting the EP bit during a PCI-Express read or write transaction invalidates the entire data payload, requiring the system to retransmit the entire packet. Even if there is only a single parity error, in one doubleword (DW) out of a large PCI data payload, the EP bit invalidates the entire transaction. This results in increased operational latency, and decreases overall system performance.

As a result, there is a need for a system for optimizing PCI-Express communications, particularly read or write transactions, that processes PCI data parity bit errors without invalidating an entire data payload within which the parity bit error occurs-providing stable and efficient error detection and correction, without negatively impacting system performance, in an easy, cost-effective manner.

### SUMMARY OF THE INVENTION

The present invention provides a versatile system for optimizing PCI-Express communications, particularly read or write transactions, in an easy, cost-effective manner. The present invention provides structures and methods for processing PCI data parity bit errors without invalidating an entire data payload within which the parity bit error occurs. The system of the present invention provides stable and efficient PCI-Express detection and correction of PCI data errors, without negatively impacting system performance. Specifically, the present invention provides structure and methods that, upon detection of a PCI parity bit error, segregate the data payload packet under transmission into several segments. The DW within which the error occurs is identified. Any portion of the data payload preceding the invalid DW is truncated just prior to the invalid DW and transmitted as a valid packet. Any portion of the data payload following the invalid DW is also separated from that DW and transmitted as a valid packet. The invalid DW itself is transmitted, with indication that it contains invalid data. Thus, by the present invention, re-transmission of data payload is limited to only the portion within which an error occurred. The present invention thus optimizes the efficiency of PCI-Express communications during the handling of PCI parity bit errors, overcoming limitations associated with conventional methodologies.

More specifically, the present invention provides a method of conducting communication between a PCI function and a PCI-Express function. The method comprises providing a PCI-Express function, and a PCI function interfaced to the PCI-Express function. A segregation structure is provided within the PCI-Express function. A data transmission from the PCI function to the PCI-Express function is initiated, and the data transmission is routed through the segregation structure. The segregation structure is operated such that corrupted data within the data transmission is identified and separated from uncorrupted data within the data transmission. The corrupted data is transmitted separately from the uncorrupted data.

The present invention also provides a PCI-Express to PCI bridge device comprising a communicative link between the bridge device and a PCI-Express device, as well as a communicative link between the bridge device and a PCI device. A data storage structure is disposed within the bridge device. A segregation structure is also disposed within the bridge device. The segregation structure is adapted to: receive a data transmission from the PCI device, identify and separate corrupted data within the data transmission from uncorrupted data within the data transmission, and store the data transmission in the data storage structure until the data transmission is forwarded to the PCI-Express device.

The present invention further provides a system for optimizing PCI-Express communications between a PCI function and a PCI-Express function. The system comprises a bridge device communicatively intercoupled between the PCI function and the PCI-Express function. A data storage structure is disposed within the bridge device, and adapted to store data that is to be transmitted to the PCI-Express function. The system also comprises a segregation structure disposed within the bridge device. The segregation structure is adapted to: receive a data transmission from the PCI function, store the data transmission in the data storage structure, identify and separate corrupted data within the data transmission from uncorrupted data within the data transmission, and transmit the corrupted data separately from the uncorrupted data.

Other features and advantages of the present invention will be apparent to those of ordinary skill in the art upon reference to the following detailed description taken in conjunction with the accompanying drawings.

### BRIEF DESCRIPTION OF THE DRAWINGS

For a better understanding of the invention, and to show by way of example how the same may be carried into effect, reference is now made to the detailed description of the invention along with the accompanying figures in which corresponding numerals in the different figures refer to corresponding parts and in which:

FIG. 1 is an illustration of one embodiment of a PCI-Express system according to the present invention;

FIG. 2 is an illustration depicting one embodiment of a packet structure according to the PCI-Express standard;

FIG. 3 is an illustration of another embodiment of a PCI-Express system according to the present invention; and

FIG. 4 is an illustration of another embodiment of a PCI-Express system according to the present invention.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. The invention will now be described in conjunction with read or write transactions within a PCI-Express architecture. The specific embodiments discussed herein, however, are merely illustrative of specific ways to make and use the invention and do not limit the scope of the invention.

The present invention provides structures and methods for processing PCI data parity bit errors without invalidating an entire data payload within which the parity bit error occurs. More specifically, the present invention provides structure and methods that, upon detection of a PCI parity bit error, segregate the data payload packet under transmission into several segments. The smallest identifiable payload segment within which the PCI parity bit error occurs is identified. In PCI-Express (hereinafter abbreviated PCI-X), this smallest segment is a doubleword (DW). Any portion of the data payload preceding the invalid DW is truncated, just prior to the invalid DW. That portion is transmitted as a valid packet. Any portion of the data payload following the invalid DW is also separated from the invalid DW. That portion is also transmitted as a valid packet. The invalid DW itself is transmitted, with indication that it contains invalid data. The present invention thus limits re-transmission of data payload to only the portion (i.e., a singe DW) within which an error occurred.

Certain aspects and embodiments of the present invention are described herein with reference to terms and concepts from the PCI Express Base Specification. That specification is hereby incorporated by reference.

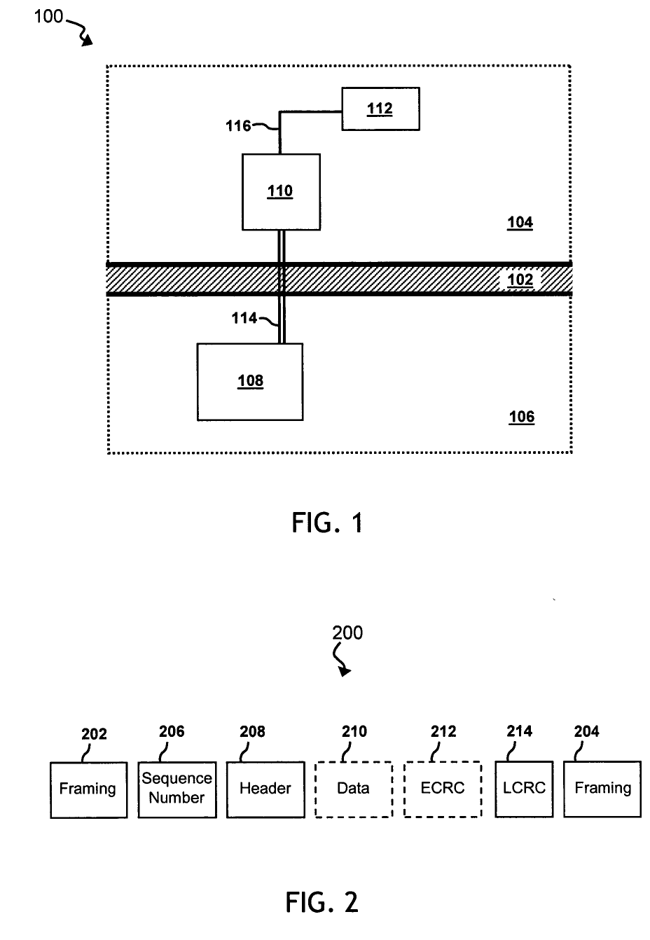

The present invention is now described with reference to FIG. 1. System 100 of FIG. 1 provides an illustrative example of an interface 102 between a PCI-X environment 104 and a PCI environment 106. For purposes of explanation and illustration, interface 102 may be considered to be any available physical or functional coupling or connection (e.g., socket, bus) between environments 104 and 106 suitable for performance in accordance with the present invention. System 100 comprises a PCI-based function 108, disposed “downstream” of a PCI-X-based function 110 (i.e., the PCI-X function 110 is in a host environment, PCI function 108 is in a peripheral environment). Functions 108 and 110 may comprise any physical or operational devices or structures (e.g., hardware, software) that operate in conformance with the present invention. In most applications, function 110 is referred to as a bridge, providing much or most of the PCI to PCI-X translation functionality.

This particular embodiment is particularly illustrative of application of the present invention to transactions that write from PCI environment 106 to PCI-X environment 104. Another embodiment, illustrative of a transaction reading from a PCI environment to a PCI-X environment, is described hereinafter. In system 100, function 108 initiates a write transaction intended for device 112 within PCI-X environment 104. A communicative link 114 is established, through interface 102, between function 108 and function 110. Another communicative link 116 is established between function 110 and device 112, for routing the data traffic received from function 108.

Referring now to FIG. 2, a transmission packet 200 according to the PCI-Express standard is depicted. Packet 200 is comprised of several segments, including framing segments 202 and 204. Framing segment 202 indicates start-of-packet (SOP), and framing segment 204 indicates end-of-packet (EOP). Packet 200 further comprises sequence number segment 206, header segment 208, data payload segment 210, ECRC segment 212 and LCRC segment 214. Located after the header 208 and data 210 segments, ECRC segment 212 is an end-to-end cyclic redundancy check (ECRC) code error detection segment, while LCRC segment 214 is a link-to-link cyclic redundancy check (LCRC) code error detection segment.

PCI is a burst mode transmission protocol. In general terms, this means that once PCI transmission begins, data words will continue to be transmitted until the PCI limit has been reached. As a result, for a PCI transaction, data payload 210 in packet 200 can be quite large. PCI error detection generally consists of a single parity bit at the end of each 32-bit word.

For purposes of illustration, assume that system 100 operates according to the conventional PCI Express Base Specification. Function 110 begins receiving a PCI burst-mode write transaction from function 108 via link 114. Function 110 stores the received data payload, in a first-in, first-out (FIFO) format, for transmission on to device 112 only after the entire data payload has been received. This scheme, however, can lead to a number of problems—especially when a parity bit error (PERR) is signaled within the PCI data payload.

Under the conventional PCI Express Base Specification, once a parity bit error is detected within data payload 210, a process of error forwarding is initiated. The entire packet 200 is “poisoned” by setting a field (i.e., the EP field) within header 208 to a certain predetermined value (i.e., lb)—indicating to a receiver of the packet that, somewhere in the data payload 210, there is corrupt data. The PCI Express Base Specification, however, does not define any mechanism for determining which part or parts of the data payload of a poisoned packet are actually corrupt and which, if any, are not corrupt. Thus, system 100 must initiate a retransmission of the entire packet 200. Especially in cases where data payload 210 contains a large amount of PCI burst-mode data, this all-or-nothing approach increases system latency and degrades system efficiency and performance significantly.

In contrast, according to the present invention, the entire packet 200 is not poisoned in the event of a parity bit error. According to the present invention, the system does determine which part or parts of the data payload of a poisoned packet are actually corrupt and which, if any, are not corrupt. According to the present invention, any portion of the data payload preceding a corrupt word is truncated immediately prior to the corrupt word and is then transmitted as a separate and complete error-free packet. The present invention determines what, if any, portion of the data payload, following the corrupt word, is error-free and transmits that portion as a separate and complete error-free packet also. The corrupt portion of the data payload is processed in standard error forwarding format-forming and transmitting a separate poisoned packet. Thus, according to the present invention, only the corrupt portion or portions of a PCI transaction need to be retransmitted. In cases where the data payload contains large amounts of PCI burst-mode data, system latencies and efficiency are optimized.

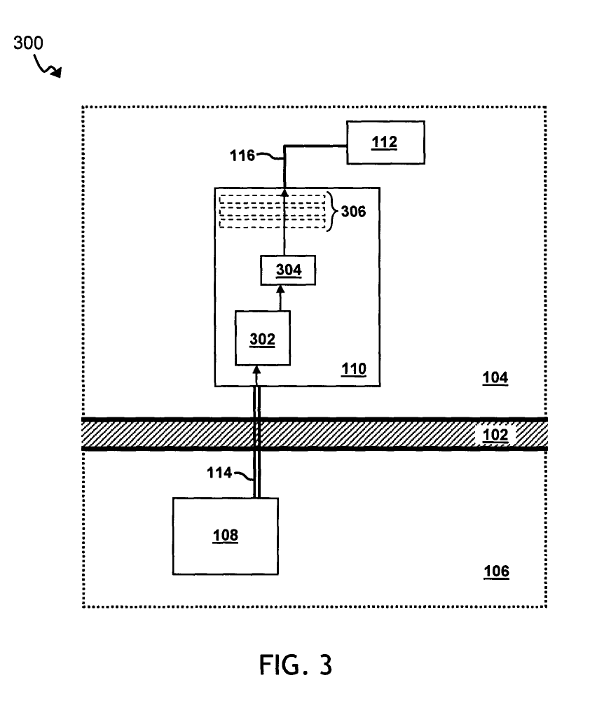

The present invention is now described in greater detail with reference to FIG. 3. FIG. 3 depicts a system 300, according to the present invention, comprising the same constituent elements as system 100. In reference to system 300, however, function 110 is described in greater detail. Function 110 comprises a segregation structure 302. Transaction data is routed through structure 302. Structure 302 receives the write transaction data from link 114, processes the transaction data, and loads it into a FIFO storage structure 304—for eventual transmission, through the various protocol layers 306 of function 110, onto target device 112. As structure 302 processes data payload 210, it evaluates the parity error status for each word of the payload, utilizing a suitable parity calculation function (not shown). Upon determining that a parity bit error has occurred for a specific data word, structure 300 halts processing of that data word. Structure 302 initiates transmission of the data already loaded into storage structure 304 as a complete packet—generating the necessary CRC and framing segments to complete that packet. This non-corrupt packet is transmitted on through the protocol layers 306 of function 110 to target device 112. Structure 302 generates the necessary CRC and framing segments to form a complete packet from the corrupt data. This includes setting the EP field in header 208 to the required error transmission value. Structure 302 initiates transmission of the corrupt data packet to target device 112, and retransmission of that data is then initiated. To the extent that any non-corrupt data follows the corrupt data, structure 302 initiates transmission of that non-corrupt data as a complete packet—generating the necessary CRC and framing segments. This non-corrupt packet is transmitted on through the protocol layers 306 of function 110 to target device 112.

Since PCI-X environment 104 provides for transaction reordering, the order in which structure 302 performs transmission of corrupt and non-corrupt packets may be varied, depending upon the specific requirements of a given system. In some embodiments, it may be advantageous for structure 302 to isolate the corrupt data, transmit it as a poisoned packet, and initiate retransmission of that data prior to processing the non-corrupt data that precedes and follows the corrupt data. In other embodiments, it may be advantageous for structure 302 to transmit the non-corrupt data packets first, before processing the corrupt data packet. These and other combinations and variations are comprehended by the present invention.

The functions and structures described herein may be implemented in a number of ways—utilizing or combining a variety of hardware and software constructs. For example, structure 302 may be implemented in circuitry as a portion of a semiconductor device, or as a routine or algorithm operating on a processor. In some embodiments, structure 302 comprises its own separate parity calculation function. In other embodiments, structure 302 is communicatively linked with and utilizes a parity calculation function residing in some separate structure. In certain embodiments, structure 302 is implemented within a PCI slave portion of a bridge device. These and other similar combinations and variations are comprehended by the present invention.

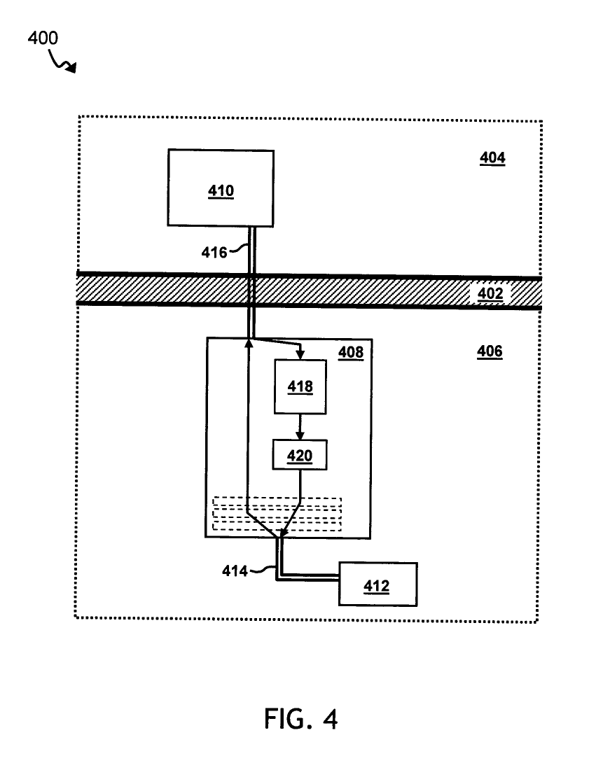

In another illustrative embodiment, the present invention is applied to transactions reading from a PCI environment to a PCI-X environment. Similar in many ways to system 100, this embodiment is now described with reference to FIG. 4. System 400 of FIG. 4 comprises an interface 402 between a PCI environment 404 and a PCI-X environment 406. System 400 comprises a PCI-X-based function 408, disposed “downstream” of a PCI-based function 410 (i.e., the PCI function 410 is in a host environment, PCI-X function 408 is in a peripheral environment). Functions 408 and 410 may comprise any physical or operational devices or structures (e.g., hardware, software) that operate in conformance with the present invention. In system 400, function 408 serves as a bridge, providing much or most of the PCI to PCI-X translation functionality.

In system 400, some device 412 within the PCI-X environment 406 initiates a read transaction intended for function 410. For example, function 410 may comprise system memory within an older, PCI computer to which a newer PCI-X peripheral 412 is attached. Device 412 is communicatively coupled to function 408 via link 414. A communicative link 416 is established, through interface 402, between function 408 and function 410. Function 408 communicates the read request to function 410, and begins receiving the data fetched from function 410.

Function 408 comprises a segregation structure 418. Again, transaction data is routed through structure 418. Structure 418 receives read transaction data from link 416, processes the transaction data, and loads it into a FIFO storage structure 420—for eventual transmission through the various protocol layers of function 408 to device 412. As structure 418 processes the data payload, it evaluates the parity error status for each word of the payload, utilizing a suitable parity calculation function (not shown). Upon determining that a parity bit error has occurred for a specific data word, structure 418 halts processing of that data word. Structure 418 initiates transmission of the data already loaded into storage structure 420 as a complete packet—generating the necessary CRC and framing segments to complete that packet. Structure 418 sets the data completion field within the header to indicate to device 412 that this is a complete packet. This non-corrupt packet is transmitted on through the protocol layers to target device 412. Structure 418 generates the necessary CRC and framing segments to form a complete packet from the corrupt data. This includes setting the EP field in header to the required error transmission value. Structure 418 initiates transmission of the corrupt data packet to target device 412, and retransmission of that data is then initiated. To the extent that any non-corrupt data follows the corrupt data, structure 418 initiates transmission of that non-corrupt data as a complete packet.

Again, since PCI-X environment 406 provides for reordering of data packets, the order in which structure 418 performs transmission of corrupt and non-corrupt packets may be varied, depending upon the specific requirements of a given system. In some embodiments, it may be advantageous for structure 418 to isolate the corrupt data, transmit it as a poisoned packet, and initiate retransmission of that data prior to processing the non-corrupt data that precedes and follows the corrupt data. In other embodiments, it may be advantageous for structure 418 to transmit the non-corrupt data packets first, before processing the corrupt data packet. These and other combinations and variations are comprehended by the present invention.

The functions and structures described herein may be implemented in a number of ways—utilizing or combining a variety of hardware and software constructs. For example, structure 418 may be implemented in circuitry as a portion of a semiconductor device, or as a routine or algorithm operating on a processor. In some embodiments, structure 418 comprises its own separate parity calculation function. In other embodiments, structure 418 is communicatively linked with and utilizes a parity calculation function residing in some separate structure.

The embodiments and examples set forth herein are presented to best explain the present invention and its practical application and to thereby enable those skilled in the art to make and utilize the invention. However, those skilled in the art will recognize that the foregoing description and examples have been presented for the purpose of illustration and example only. The description as set forth is not intended to be exhaustive or to limit the invention to the precise form disclosed. Many modifications and variations are possible in light of the above teaching without departing from the spirit and scope of the following claims.

1. A method of conducting communication between a PCI function and a PCI-Express function, the method comprising the steps of:
providing a PCI-Express function;
providing a PCI function interfaced to the PCI-Express function;
providing a segregation structure within the PCI-Express function;
initiating a data transmission from the PCI function to the PCI-Express function;
routing the data transmission through the segregation structure;
operating the segregation structure such that corrupted data within the data transmission is identified and separated from uncorrupted data within the data transmission; and
transmitting the corrupted data separately from the uncorrupted data.

2. The method of claim 1, wherein the step of initiating a data transmission further comprises initiating a write transaction from the PCI function to the PCI-Express function.

3. The method of claim 1, wherein the step of initiating a data transmission further comprises initiating a read transaction from the PCI-Express function to the PCI function.

4. The method of claim 1, wherein the step of providing a PCI-Express function further comprises providing a PCI to PCI-Express bridge device.

5. The method of claim 4, wherein the step of providing a segregation structure further comprises providing a segregation structure within a PCI slave portion of the bridge device.

6. The method of claim 1, wherein the step of operating the segregation structure further comprises providing a parity checking function, accessed by the segregation structure, that examines the data transmission for parity bit errors.

7. The method of claim 6, wherein the step of operating the segregation structure further comprises forming a separate data packet from a data word within which a parity bit error is discovered.

8. The method of claim 6, wherein the step of operating the segregation structure further comprises loading a predetermined value into a field within a header located in the separate data packet formed from the data word within which the parity bit error was discovered.

9. The method of claim 6, wherein the step of operating the segregation structure further comprises forming a separate data packet from a portion of the data transmission immediately preceding the data word within which the parity bit error was discovered.

10. The method of claim 6, wherein the step of operating the segregation structure further comprises forming a separate data packet from a portion of the data transmission immediately following the data word within which the parity bit error was discovered.

11. The method of claim 1, wherein the step of transmitting the corrupted data separately from the uncorrupted data further comprises transmitting the uncorrupted data before the corrupted data.

12. The method of claim 1, wherein the step of transmitting the corrupted data separately from the uncorrupted data further comprises transmitting the uncorrupted data after the corrupted data.

13. The method of claim 1, wherein the step of transmitting the corrupted data separately from the uncorrupted data further comprises transmitting a first portion of the uncorrupted data, then transmitting the corrupted data, and then transmitting a second portion of the uncorrupted data.

14. A PCI-Express to PCI bridge device comprising:
a communicative link between the bridge device and a PCI-Express device;
a communicative link between the bridge device and a PCI device;
a data storage structure disposed within the bridge device; and
a segregation structure disposed within the bridge device and adapted to receive a data transmission from the PCI device, to identify and separate corrupted data within the data transmission from uncorrupted data within the data transmission, and to store the data transmission in the data storage structure until the data transmission is forwarded to the PCI-Express device.

15. The device of claim 14, wherein the data transmission is a write transaction from the PCI device to the PCI-Express device.

16. The device of claim 14, wherein the data transmission is a read transaction from the PCI-Express device to the PCI device.

17. The device of claim 14, wherein the segregation structure is disposed within a PCI slave portion of the bridge device.

18. The device of claim 14, wherein the segregation structure is further adapted to access a parity checking function, disposed within the bridge device, which examines the data transmission for parity bit errors.

19. The device of claim 18, wherein the parity checking function is disposed within the segregation structure.

20. The device of claim 18, wherein the segregation structure is further adapted to form a separate data packet from a data word within which a parity bit error is discovered.

21. The device of claim 18, wherein the segregation structure is further adapted to load a predetermined value into a field within a header located in the separate data packet formed from the data word within which the parity bit error was discovered.

22. The device of claim 18, wherein the segregation structure is further adapted to form a separate data packet from a portion of the data transmission immediately preceding the data word within which the parity bit error was discovered.

23. The device of claim 18, wherein the segregation structure is further adapted to form a separate data packet from a portion of the data transmission immediately following the data word within which the parity bit error was discovered.

24. A system for optimizing PCI-Express communications between a PCI function and a PCI-Express function, the system comprising:
a bridge device communicatively intercoupled between the PCI function and the PCI-Express function;
a data storage structure disposed within the bridge device, adapted to store data to be transmitted to the PCI-Express function; and
a segregation structure disposed within the bridge device and adapted to receive a data transmission from the PCI function, to store the data transmission in the data storage structure, to identify and separate corrupted data within the data transmission from uncorrupted data within the data transmission, and to transmit the corrupted data separately from the uncorrupted data.
